(19) United States
(12) Patent Application Publication
(10) Pub. No.: US 2013/0200331 A1
(43) Pub. Date: Aug. 8, 2013

(54) SEMICONDUCTOR STORAGE DEVICE AND METHOD OF MANUFACTURING THE SAME

(71) Applicant: National Institute of Advanced Industrial Science and Technology, Tokyo (JP)

(72) Inventors: Takahiro Morikawa, Ibaraki (JP); Toshimichi Shintani, Ibaraki (JP)

(73) Assignee: National Institute of Advanced Industrial Science and Technology, Tokyo (JP)

(21) Appl. No.: 13/759,346

(22) Filed: Feb. 5, 2013

(30) Foreign Application Priority Data
Feb. 6, 2012 (JP) 2012-023345

(51) Int. Cl. H01L 45/00

(52) U.S. Cl. CPC H01L 45/1233; H01L 45/1608
USPC 257/5; 438/382

(57) ABSTRACT

In a semiconductor storage device where a plurality of memory cells obtained by connecting a vertical transistor and a phase-change element in parallel is formed along a direction perpendicular to a main face of a semiconductor substrate, highly-reliable selection operation is made possible with a further low voltage. A plurality of through-holes extending through insulating films and polysilicon layers is formed in regions at which word lines and bit lines intersect with each other. A plurality of vertical chain memories composed of a gate insulating film 111, a channel film, a reaction-preventing film, a metal silicide film having a resistance lower than that of the reaction-preventing film, a phase-change film, and an embedding insulating film is formed inside each through-hole. The channel film and the reaction-preventing film are separated into respective pieces at regions among a plurality of memory cells arranged along a direction perpendicular to a main face of a semiconductor substrate. Further, the channel films of respective memory cells are connected to one another through the metal silicide films provided in regions among the plurality of memory cells.

### CROSS-REFERENCE TO RELATED APPLICATION

The present application claims priority from Japanese Patent Application No. 2012-023345 filed on Feb. 6, 2012, the content of which is hereby incorporated by reference into this application.

### TECHNICAL FIELD OF THE INVENTION

The present invention relates to a semiconductor storage device and a technique of manufacturing the same, and in particular to an electrically-rewritable nonvolatile semiconductor storage device that utilizes a material whose electrical characteristic changes when current is caused to flow through the material to store information, and a technique of manufacturing the same.

### BACKGROUND OF THE INVENTION

In recent years, as a memory used instead of a flash memory that approaches the limit of miniaturization, resistance-changing type memories have been researched, and as one example of these memories, a phase-change memory using a phase-change material such as Ge₂Sb₂Te₅ as a recording material has been researched actively.

The phase-change memory is a resistance-changing type memory that utilizes that a recording material has different resistance values depending on its phase state to store information therein, and has a structure where a thin film (phase-change film) made of phase-change material has been sandwiched between a pair of metal electrodes. The phase-change material represented by Ge₂Sb₂Te₅ has a high resistance in its amorphous state while having a low resistance in its crystalline state. Therefore, reading-out of information is performed by measuring current flowing through the phase-change film when a potential difference is provided between both ends of a memory cell and making discrimination about a high-resistance state or a low-resistance state.

Further, in the phase-change memory, rewriting of information is performed by changing an electric resistance of the phase-change film by Joule heat generated by current to a different state. A reset operation, namely, an operation for changing the phase-change film to the amorphous state having a high resistance, is performed by causing a large amount of current to flow in the phase-change memory in a short period of time to melt the phase-change film and then rapidly reducing the current to rapidly cool the phase-change film. On the other hand, a set operation, namely, an operation for changing the phase-change film to the crystalline state having a low resistance, is performed by causing current sufficient to hold the phase-change film in a crystallization temperature to flow in the phase-change memory for a long period of time.

The above-described phase-change memory has such a feature that current required to change the phase state of the phase-change film becomes smaller according to proceeding with miniaturization of the phase-change memory, and since the phase-change memory is suited for miniaturization in principle, researches thereof have been performed actively.

Japanese Patent Application Laid-Open Publication No. 2008-160004 (Patent Document 1) discloses, as how to perform high integration of the phase-change memory, a technique of forming a stacked body by stacking gate electrodes and insulating films on a semiconductor substrate alternately in a plural layer-stacking state, then forming a plurality of through-holes extending through all layers of the stacked body by a batch working, and forming memory cells where a vertical transistor and a phase-change element have been connected in parallel by causing a gate insulating film, a channel layer and a phase-change film to deposit inside the through-holes.

Incidentally, Symposium on VLSI technology, pp. 136-137 (2009) (Non-Patent Document 1) discloses a NAND-type flash memory having a stacking structure similar to that disclosed in the above-described Patent Document 1.

### SUMMARY OF THE INVENTION

However, as a result of consideration about the above-described Patent Document 1 which has been performed by the present inventors, it has been found that a serious problem is involved in the phase-change memory described in this Patent Document 1. The problem will be described below.

First of all, an operation method of the phase-change memory described in the Patent Document 1 will be described. As described above, the phase-change memory has such a structure that a plurality of through-holes is formed in a stacked body obtained by stacking gate electrodes and insulating films alternately in a plural layer-stacking state and a plurality of vertical transistors formed in these through-holes is connected in series, and phase-change films (phase-change elements) are connected to the plurality of vertical transistors in parallel, respectively.

FIG. 1A is a sectional view showing some (two memory cells) of a plurality of memory cells formed in the through-hole, and FIG. 1B shows an equivalent circuit of the memory cells. Inside one through-hole 110, a phase-change film 121, a reaction-preventing film 113, and a channel film 112 composed of a silicon film are formed from a center side of the through-hole 110 toward a side wall side thereof. Further, gate electrodes 21 and 22 are arranged via gate insulating films 111 composed of a silicon oxide film in the vicinity of the side wall of the through-hole 110. Further, an insulating film 11, 12, or 13 is formed between the gate electrode 21 and the gate electrode 22.

When the vertical transistor is in an ON state, current flows in the channel film 112 of the vertical transistor. This is because even when the phase-change film 121 is in a low-resistance state, the resistance thereof is larger than an ON resistance of the vertical transistor. When information is written in the memory cell shown in FIG. 1, the vertical transistor of a selected cell (the memory cell positioned on the lower side in FIG. 1) is turned OFF. In the selected cell where the vertical transistor is in the OFF state, current cannot flow in the channel film 112 but flows in the phase-change film 121 in a bypassing fashion. That is, the current flows along a route shown by an arrow in FIG. 1A. At this time, since Joule heat is generated in the phase-change film 121 in which current has been caused to flow, a resistance of the phase-change film 121 is changed. Therefore, by changing the magnitude of the current, operations (writing, erasing and reading) of the selected cell can be made possible.

The problem involved in the phase-change memory having such a structure lies in such a point that a resistance of a connection portion where a vertical transistor and the phase-change film 121 constituting one memory cell are connected in parallel is very high. In the phase-change memory described in the Patent Document 1, the reaction-preventing film 113 is provided between the channel film 112 and the phase-change film 121. The reaction-preventing film 113 is a film for preventing performance deterioration of the phase-change memory due to reaction of the phase-change film 121 with the channel film 112 adjacent thereto or mutual diffusion between the phase-change film 121 and the channel film 112 according to temperature rising of the phase change film 121 of the selected cell during writing operation and erasing operation of the phase-change memory, and is composed of a thin SiN film having a thickness of, for example, about 1 nm.

Since the reaction-preventing film 113 is formed inside the through-hole 110 entirely, it is necessary to cause current to flow across the reaction-preventing film 113 in order to cause current to flow in the phase-change film 121 of the selected cell. Though current of about several tens μA can be caused to flow in the reaction-preventing film 113, since the resistance of the reaction-preventing film 113 is very high, a high voltage is required to cause current to flow in the phase-change film 121.

That is, in the phase-change memory described in the Patent Document 1, the vertical transistor and the phase-change film 121 to be connected to each other in parallel are connected to each other via very large resistances 113R, as shown in the equivalent circuit diagram in FIG. 1B. Therefore, a large voltage is required in order to cause current to flow in the phase-change film 121 while bypassing the channel film 112, and in some cases, there is a possibility that the voltage exceeds a withstanding voltage between the source and the drain of the vertical transistor put in the OFF state to break the vertical transistor. Further, when the resistance of the connection portion between the vertical transistor and the phase-change film 121 becomes high, even if the phase-change film 121 changes between the high-resistance state and the low-resistance state, contrast of a reading-out resistant value becomes low, so that such a problem also occurs that discrimination between the high-resistance state and the low-resistance state becomes difficult.

Another problem of the phase-change memory described in the Patent Document 1 lies in that a resistance 21R exists between the vertical transistors positioned adjacent to each other in a vertical direction of the through-hole and connected in series, as shown in the equivalent circuit diagram in FIG. 1B. Since the conductance of the channel film 112 formed in the connection portion cannot be controlled by a gate voltage, it functions as a large resistance component. Further, since a voltage is also applied to the resistance 21R, such a problem occurs that the channel film 112 blocks the low-voltage operation.

A method for thinning the film thickness of the insulating film 11, 12, or 13 formed between the gate electrode 21 and the gate electrode 22 can be adopted in order to shorten the length of the connection portion. In the case, however, the distance between memory cells adjacent to each other in the vertical direction becomes short, Joule heat generated when information is written in the selected cell propagates up to the phase-change film 121 of a unselected memory cell adjacent to the selected cell, so that a problem where information which has been recorded in the unselected memory cell is erased, a problem of the so-called thermal disturbance may occur.

Incidentally, since the NAND type flash memory shown in the Non-Patent Document 1 adopts a system where writing of information is performed by applying a high voltage to a gate electrode and causing a charge trapping film positioned between the gate electrode and a channel to hold electrons, it is largely different in writing principle of information from the resistance-changing type memory configured to cause current to flow in the storage element itself. Therefore, the technique applied to the NAND type flash memory cannot be applied to the resistance-changing type memory as it is.

An object of the present invention is to provide a technique which solves a problem such as described above at an operation time of a phase-change memory and can perform highly-reliable selection operations (writing, erasing, and reading) with a further low voltage in a semiconductor storage device having a phase-change memory where a vertical transistor and a phase-change resistance film are connected in parallel.

The above and other objects and novel characteristics of the present invention will be apparent from the description of the present specification and the accompanying drawings.

The typical ones of the inventions disclosed in the present application will be briefly described as follows.

(1) In a semiconductor storage device according to an embodiment of the present invention where a plurality of memory cells obtained by connecting a vertical transistor and a phase-change element whose resistant value is changed by current in parallel is formed along a first direction perpendicular to a main face of a semiconductor substrate, a stacked body obtained by stacking (N+1) insulating layers and N gate semiconductor layers alternately and a plurality of through-holes extending through the stacked body in the first direction are formed on the main face of the semiconductor substrate, where N is a natural number, a gate insulating film of the vertical transistor, a channel film of the vertical transistor, a reaction-preventing film, and a phase-change film constituting the phase-change element are formed inside each of the plurality of through-holes, and the reaction-preventing film is separated into respective pieces at regions among the plurality of memory cells formed along the first direction.

(2) In a semiconductor storage device according to an embodiment of the present invention where a plurality of memory cells obtained by connecting a vertical transistor and a phase-change element whose resistant value is changed by current in parallel is formed along a first direction perpendicular to a main face of a semiconductor substrate, a stacked body obtained by stacking (N+1) insulating layers and N gate semiconductor layers alternately and a plurality of through-holes extending through the stacked body in the first direction are formed on the main face of the semiconductor substrate, where N is a natural number, a gate insulating film of the vertical transistor, a channel film of the vertical transistor, a metal silicide film, and a phase-change film constituting the phase-change element are formed inside each of the plurality of through-holes, and the channel film is separated into respective pieces at regions among the plurality of memory cells formed along the first direction, and besides, the channel films are connected to each other via the metal silicide film.

(3) In a manufacturing method of a semiconductor storage device according to an embodiment of the present invention where a plurality of memory cells obtained by connecting a vertical transistor and a phase-change element whose resistant value is changed by current in parallel is formed along a first direction perpendicular to a main face of a semiconductor substrate, the manufacturing method includes: (a) a step of forming a stacked body obtained by stacking (N+1) insulating layers and N gate semiconductor layers alternately on the main face of the semiconductor substrate, where N is a natural number; (b) a step of forming a plurality of through-holes extending through the stacked body along the first direction; (c) a step of isotropically-etching the N gate semiconductor layers exposed to side walls of insides of the plurality of through-holes to perform setting-back laterally; (d) a step of embedding a gate insulating film of the vertical transistor, a channel film of the vertical transistor, and a reaction-preventing film into the plurality of through-holes in this order after the step (c); (e) a step of anisotropically-etching the reaction-preventing film to separate the reaction-preventing film into respective pieces at regions among the plurality of memory cells formed in the first direction; and (f) a step of embedding a phase-change film constituting the phase-change element into the plurality of through-holes after the step (e).

The effects obtained by typical aspects of the present inventions disclosed in the present application will be briefly described below.

A semiconductor storage device which operates with a further low voltage and can perform highly-reliable selection operations (writing, erasing, and reading) can be realized.

### BRIEF DESCRIPTIONS OF THE DRAWINGS

FIGS. 1A and 1B are a sectional view showing some of a plurality of memory cells formed inside a through-hole and an equivalent circuit diagram thereof, for explaining a problem involved in a conventional art;

FIG. 2 is a plan view of a whole semiconductor storage device which is an embodiment of the present invention;

FIG. 3 is a perspective view diagrammatically showing a portion of the semiconductor storage device which is the embodiment of the present invention;

FIG. 4 is a perspective view showing a configuration of a memory cell array of the semiconductor storage device which is the embodiment of the present invention;

FIG. 5 is a graph showing a temperature change of a phase-change film during rewriting operation of the semiconductor storage device which is the embodiment of the present invention;

FIGS. 6A to 6D are a sectional view of a portion of a memory cell array, a plan view of an insulating film shown in FIG. 6A as viewed from the above, a plan view of a gate polysilicon layer shown in FIG. 6A as viewed from the above, and an equivalent circuit diagram showing the portion of the memory cell array shown in FIG. 6A, for explaining a reset operation, a set operation, and a read-out operation of the semiconductor storage device which is the embodiment of the present invention;

FIG. 7 is a circuit diagram of a memory cell array for explaining the reset operation, the set operation, and the read-out operation of the semiconductor storage device which is the embodiment of the present invention;

FIG. 8 is a perspective view of a memory cell array showing a step in a manufacturing method of a semiconductor storage device which is the embodiment of the present invention;

FIG. 9 is a perspective view of the memory cell array showing a step following to FIG. 8 in the manufacturing method of a semiconductor storage device;

FIG. 10 is a perspective view of the memory cell array showing a step following to FIG. 9 in the manufacturing method of a semiconductor storage device;

FIG. 11 is a perspective view of the memory cell array showing a step following to FIG. 10 in the manufacturing method of a semiconductor storage device;

FIG. 12 is a perspective view of the memory cell array showing a step following to FIG. 11 in the manufacturing method of a semiconductor storage device;

FIG. 13 is a perspective view of the memory cell array showing a step following to FIG. 12 in the manufacturing method of a semiconductor storage device;

FIG. 14 is a perspective view of the memory cell array showing a step following to FIG. 13 in the manufacturing method of a semiconductor storage device;

FIG. 15 is a perspective view of the memory cell array showing a step following to FIG. 14 in the manufacturing method of a semiconductor storage device;

FIG. 16 is a perspective view of the memory cell array showing a step following to FIG. 15 in the manufacturing method of a semiconductor storage device;

FIG. 17 is a perspective view of the memory cell array showing a step following to FIG. 16 in the manufacturing method of a semiconductor storage device;

FIG. 18 is a perspective view of the memory cell array showing a step following to FIG. 17 in the manufacturing method of a semiconductor storage device;

FIG. 19 is a perspective view of the memory cell array showing a step following to FIG. 18 in the manufacturing method of a semiconductor storage device;

FIG. 20 is a perspective view of the memory cell array showing a step following to FIG. 19 in the manufacturing method of a semiconductor storage device;

FIG. 21 is a perspective view of the memory cell array showing a step following to FIG. 20 in the manufacturing method of a semiconductor storage device;

FIG. 22 is a perspective view of the memory cell array showing a step following to FIG. 21 in the manufacturing method of a semiconductor storage device;

FIG. 23 is a perspective view of the memory cell array showing a step following to FIG. 22 in the manufacturing method of a semiconductor storage device;

FIG. 24 is a perspective view of the memory cell array showing a step following to FIG. 23 in the manufacturing method of a semiconductor storage device;

FIG. 25 is a perspective view of the memory cell array showing a step following to FIG. 24 in the manufacturing method of a semiconductor storage device;

FIG. 26 is a perspective view of the memory cell array showing a step following to FIG. 25 in the manufacturing method of a semiconductor storage device; and

FIG. 27 is a perspective view of the memory cell array showing a step following to FIG. 26 in the manufacturing method of a semiconductor storage device.

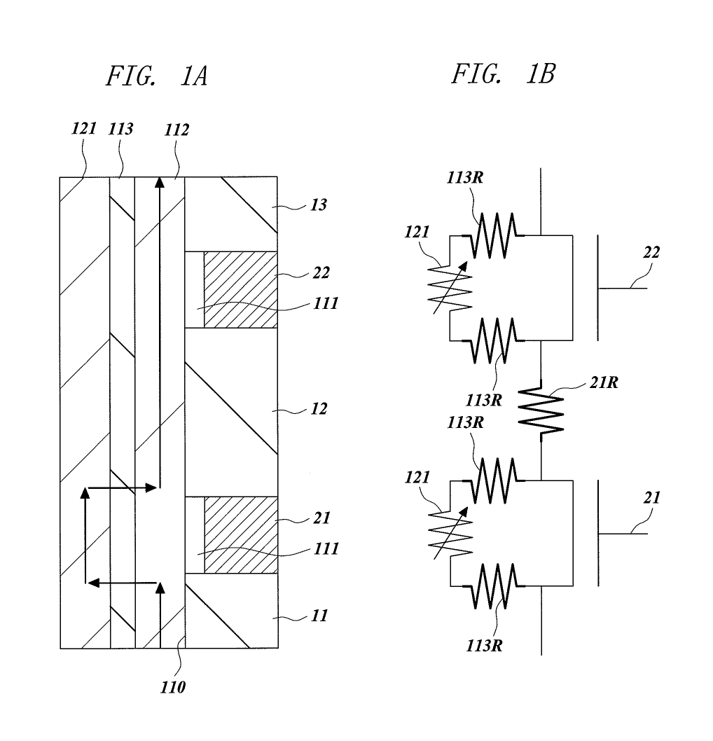

### DESCRIPTIONS OF THE PREFERRED EMBODIMENTS

Hereinafter, an embodiment of the present invention will be described in detail with reference to the accompanying drawings. Note that components having the same function are denoted by the same reference symbols throughout the drawings for describing the embodiment, and the repetitive description thereof will be omitted. In addition, the description of the same or similar portions is not repeated in principle unless particularly required in the following embodiment. Further, in some drawings for explaining the embodiment, hatching is used even in a plan view and hatching is omitted even in a cross-sectional view so as to easily understand the configuration.

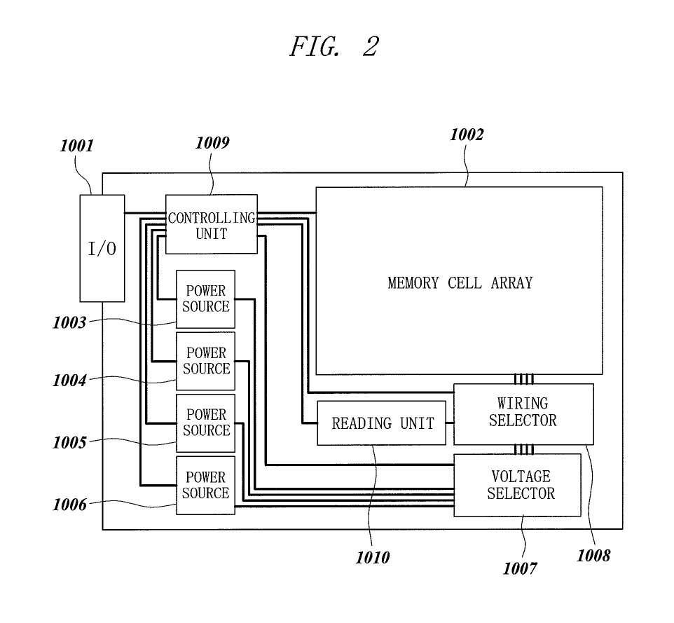

FIG. 2 is a plan view of a whole semiconductor storage device of the embodiment. As shown in FIG. 2, the semiconductor storage device according to the embodiment is provided with an I/O interface 1001 including an input and output buffer for transmission and reception of information to/from an external device (not shown) and the like, a memory cell array 1002, a plurality of power sources 1003 to 1006 which supply a plurality of voltages different from one another, respectively, a voltage selector 1007 which selects a voltage of voltages from the power sources 1003 to 1006, a wiring selector 1008 which selects a connection destination of an output from the voltage selector 1007 from wires (bit lines, word lines, and the like described later) of the memory cell array 1002, and a control section 1009 which performs control of the whole device. The wiring selector 1008 is connected with a reading section 1010 having a sense amplifier and the like.

When information is inputted from the external device into the I/O interface 1001, the control section 1009 selects a voltage for writing information by the voltage selector 1007, produces a voltage pulse in either of the power sources 1003 to 1006, and supplies the voltage pulse to predetermined wires within the memory cell array 1002 using the wiring selector 1008. Thereby, information is written in a phase-change memory cell within the memory cell array 1002.

Further, when a signal for reading out information is inputted into the I/O interface 1001 from the external device, the control section 1009 selects a voltage for reading information by the voltage selector 1007, produces a voltage in either of the power sources 1003 to 1006, and supplies the voltage produced to predetermined wires of the memory cell array 1002 via the wiring selector 1008. As a result of supplying the voltage, current read out is read in the reading section 1010, so that information which has been stored is produced and the information is supplied to the external device via the control section 1009 and the I/O interface 1001.

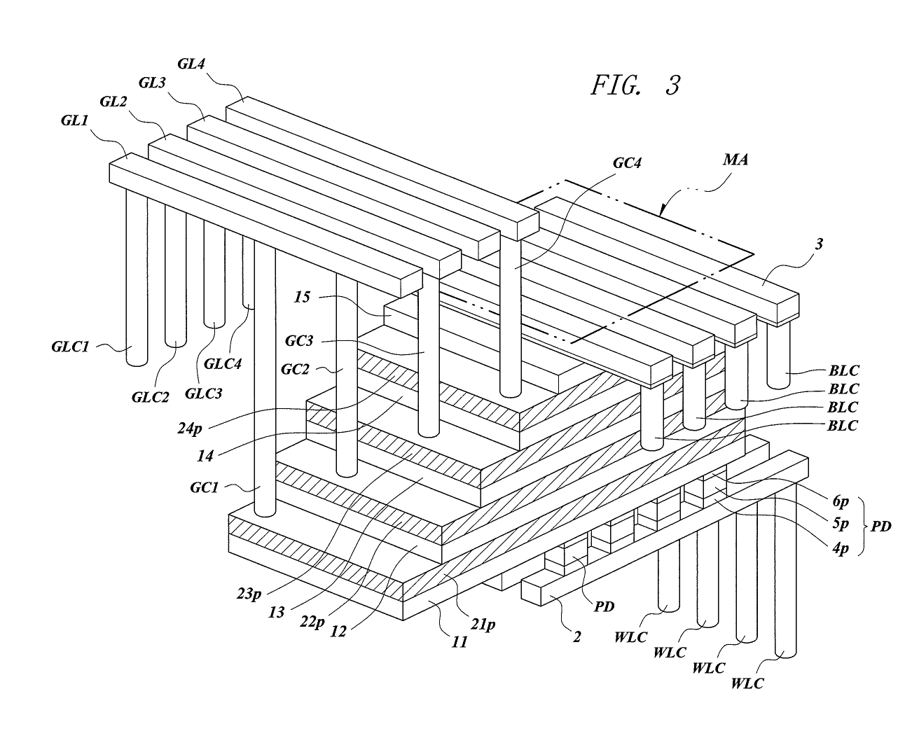

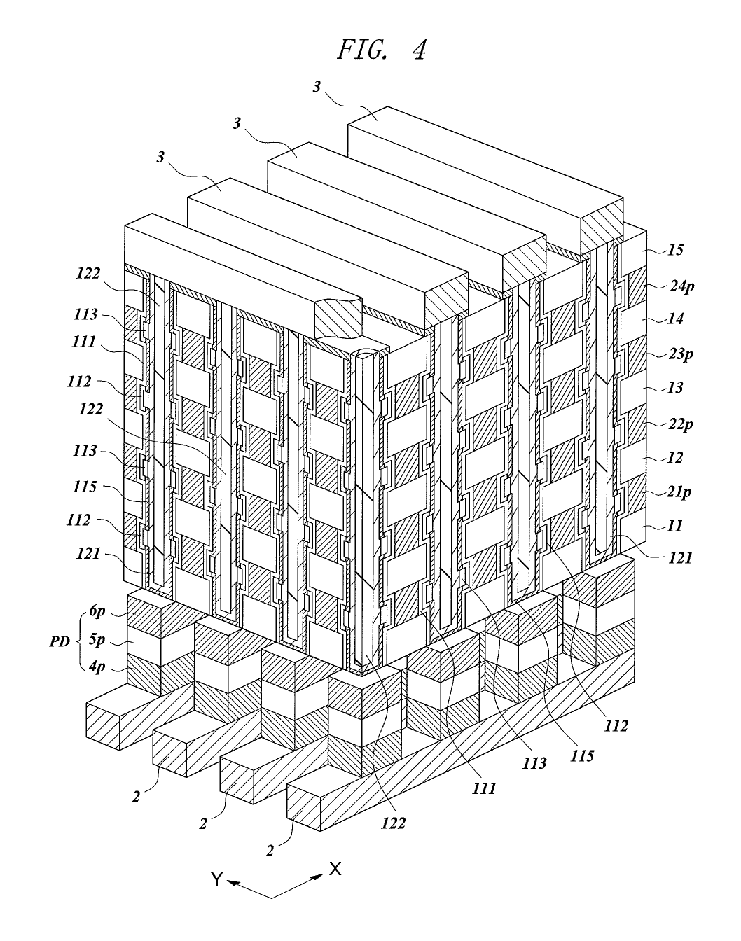

FIG. 3 is a perspective view diagrammatically showing a portion of the semiconductor storage device according to the embodiment, where a portion of a memory cell array MA, some of wires, and some of contacts are shown. Specifically, a portion composed of word lines 2 made of a metal wire, word line contacts WLC connecting the word lines 2 and the wiring selector 1008 shown in FIG. 2, diodes PC formed of a polysilicon layer 4p doped with p-type impurities, a polysilicon layer 5p doped with low-level impurities, and a polysilicon layer 6p doped with n-type impurities, gate polysilicon layers (gate semiconductor layers) 21p, 22p, 23p, and 24p, gate wires GL1, GL2, GL3, and GL4 for feeding current to the gate polysilicon layers 21p, 22p, 23p, and 24p, contacts GC1, GC2, GC3, and GC4 for connecting the gate polysilicon layers 21p, 22p, 23p, and 24p and the gate wires GL1, GL2, GL3, and GL4, respectively, contacts GLC1, GLC2, GLC3, and GLC4 for connecting the gate wires GL1, GL2, GL3, and GL4 and the wiring selector 1008, bit wires 3 made of a metal wire, contacts BLC for connecting the bit lines 3 and the wiring selector 1008 shown in FIG. 2, an insulating film layer 11 positioned between the diodes PD and the gate polysilicon layer 21p, insulating films 12, 13, and 14 among the gate polysilicon layers 22p, 23p and 24p, and an insulating film 15 positioned between the gate polysilicon layer 24p and the bit lines 3 is shown in FIG. 3.

Incidentally, here, an example where four gate polysilicon layers 21p, 22p, 23p and 24p have been stacked one on another has been shown, but the stacking number of gate polysilicon layers can be determined arbitrarily.

FIG. 4 is a perspective view showing the configuration of the memory cell array MS shown in FIG. 3 in detail. A plurality of word lines 2 extend in an X direction above the semiconductor substrate which is not shown in FIG. 4. A plurality of diodes PD (polysilicon layers 4p, 5p, and 6p) are arranged in a lattice pattern along the X direction and a Y direction above the plurality of word lines 2. A plurality of bit lines 3 extend in the Y direction in an uppermost portion above the semiconductor substrate.

The insulating films 11, 12, 13, 14, and 15 and the gate polysilicon layers 21p, 22p, 23p, and 24p are stacked alternately between the bit lines 3 and the diodes PD. Further, a plurality of through-holes extending through the insulating films 11, 12, 13, 14, and 15 and the gate polysilicon layers 21p, 22p, 23p and 24p is formed in regions at which the word lines 2 intersect with the bit line 3. A plurality of vertical chain memories formed of a gate insulating film 111, a channel film 112, a reaction-preventing film 113, a metal silicide film 115 having a resistance lower than that of the reaction-preventing film 113, a phase-change film (phase-change element) 121, and an embedding insulating film 122 is formed inside each through-hole.

As shown in FIG. 4, the channel film 112 and the reaction-preventing film 113 are separated into respective pieces by regions among a plurality of memory cells arranged in a direction perpendicular to a main face of the semiconductor substrate. Further, the channel films 112 of respective memory cells are connected by metal silicide films 115 provided in regions among the plurality of memory cells.

The semiconductor storage device according to this embodiment utilizes such a point that resistance values of a phase-change material such as Ge₂Sb₂Te₅, constituting the phase-change film 121, are different between its amorphous state and in its crystalline state to store memory cell information therein. The phase-change material such as Ge₂Sb₂Te₅ has a high resistance value in the amorphous state, while it has a low resistance value in the crystalline state, so that reading-out of information is performed by providing a potential difference between both ends of the phase-change film 121, measuring current flowing in the phase-change film 121, and performing discrimination about the high-resistant state or the low-resistant state.

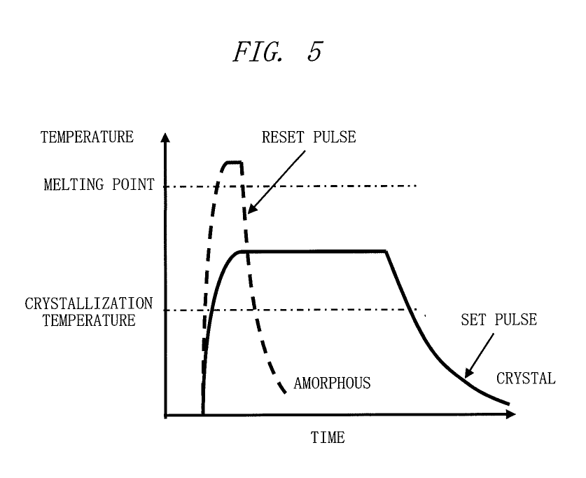

FIG. 5 is a graph showing a temperature change of a phase-change film during rewriting operation of the semiconductor storage device according to the embodiment.

An operation for changing the phase-change film from the high-resistant state (amorphous state) to the low-resistant state (crystalline state), namely, a set operation, and on the contrary, an operation for changing the phase-change film from the low-resistant state (crystalline state) to the high-resistant state (amorphous state), namely, a reset operation can be performed by providing a temperature change such as shown in FIG. 5 to the phase-change film. Specifically, changing to the crystalline state is performed by heating the phase-change film in the amorphous state to a crystallization temperature or higher and holding the temperature for about 10⁻⁶ seconds or more. Further, the phase-change film in the crystalline state can be changed to the amorphous state by heating the phase-change film up to a melting point thereof or higher to change the same to a melted state and rapidly cooling the same.

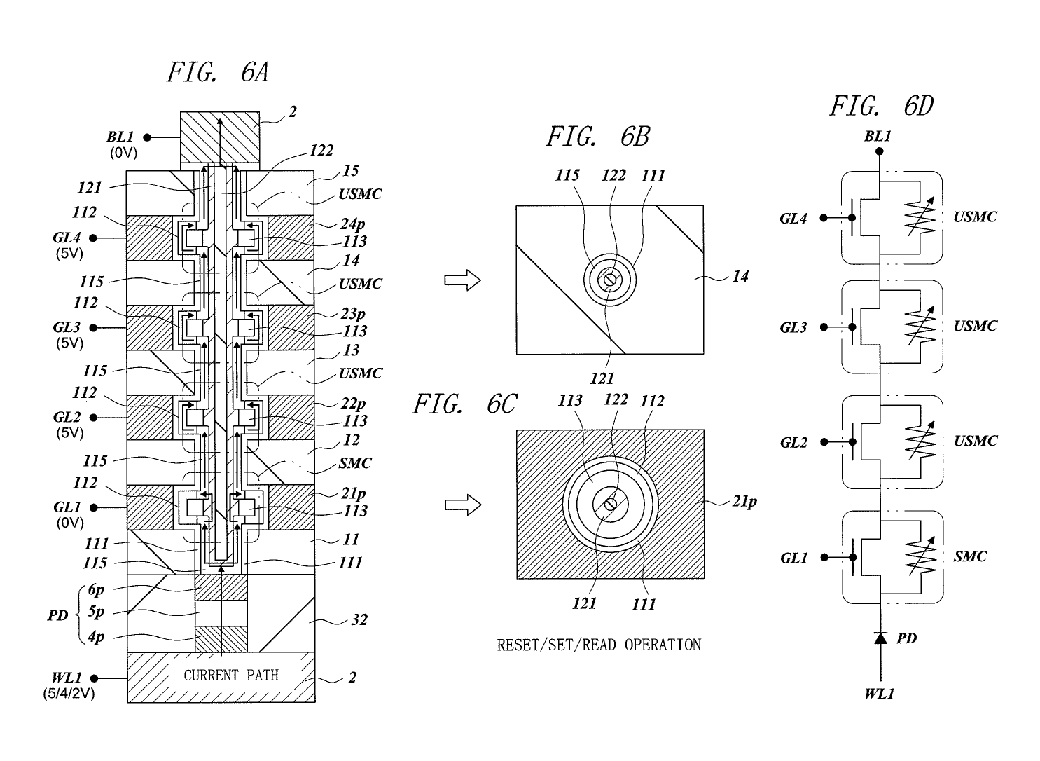

Next, an operation of the memory cell will be described with reference to FIG. 6. FIG. 6 is a sectional view of a portion (a intersecting area between one word line 2 and one bit line 3) of the memory cell array shown in FIG. 3 and FIG. 4, a plan view of the insulating film 14 shown in FIG. 6A as viewed from the above, a plan view of the gate polysilicon layer 21p shown in FIG. 6A as viewed from the above, and an equivalent circuit diagram of the portion shown in FIG. 6A. Incidentally, though omitted in FIG. 3 and FIG. 4, an insulating film 32 for electrically separating diodes PD adjacent to each other is formed in a region between the word line 2 and the insulating film 11, as shown in FIG. 6A.

First, a voltage of 0V is applied to the gate wire GL1 connected to the gate polysilicon layer 21p of a selected cell SMC to change a transistor in the selected cell SMC to OFF state. Further, a voltage of 5V is applied to the gate wires GL2, GL3, and GL4 connected to the gate polysilicon layers 22p, 23p, and 24p of a unselected memory cell USMC to change a transistor in the unselected memory cell USMC to ON state. Further, a voltage of 0V is applied to the bit line BL1, while voltages of 5V, 4V, and 2V are applied to the word line WL1 at a reset time, at a set time, and at a read-out time, respectively.

At this time, since a resistance of the channel film 112 becomes low in the unselected memory cell USMC whose transistor is put in ON state, current flows in the channel film 112 without depending on the state of the phase-change film 121. On the other hand, current flows in the phase-change film 121 in the selected memory cell SMC whose transistor is put in OFF state. Therefore, the resistance value of the phase-change film 121 is changed at the reset operation time and at the set operation time by current flowing in the phase-change film 121 of the selected memory cell SMC. Further, a current value of current flowing in the phase-change film 121 of the selected cell SMC is determined at the read-out operation time.

In the memory cell configuration shown in the above-described Patent Document 1, when current flows in the phase-change film 121 while bypassing the channel film 112 of the selected memory cell SMC, the current must cut across the reaction-preventing film 113. In the memory cell configuration according to the embodiment, however, the reaction-preventing film 113 is split at a connection portion between memory cells adjacent to each other, and the metal silicide film 115 having a resistance value lower than that of the reaction-preventing film 113 is provided at the connection portion. Therefore, since current cuts across the metal silicide film 115 having a low resistance without being required to cut across the reaction-preventing film 113 having a high resistance, the reset operation, the set operation, and the read-out operation can be made possible with further low voltages.

Further, in the memory cell configuration according to the embodiment, the reaction-preventing film 113 is formed between a portion of the phase-change film 121 in which current flows and the channel film 112, so that when the phase-change film 121 reaches a high temperature during operation, characteristic deterioration due to reaction or mutual diffusion between the phase-change material (the phase-change film 121) and the polysilicon (the channel film 112) can be prevented. Further, since the length of the connection portion, namely, the thicknesses of the insulating layers 12, 13, and 14 among gates, can be made large while the resistance of the connection portion is kept low, adverse effect of thermal disturbance between cells adjacent to each other can be reduced.

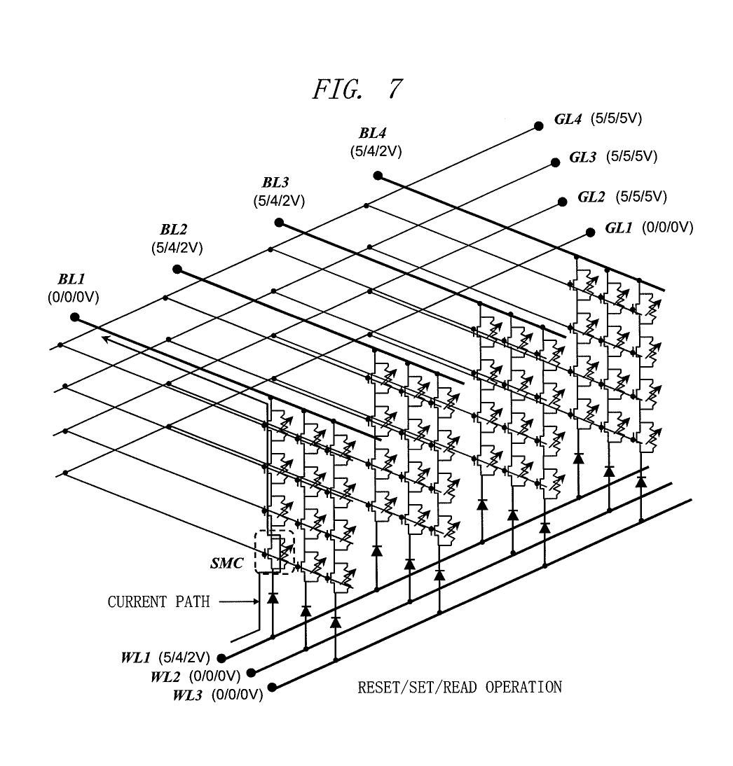

The memory cell array according to the embodiment is composed of the plurality of word lines 2, the plurality of bit lines 3, a plurality of vertical chain memories, and the plurality of diodes PD. Therefore, actual reset operation, set operation, and read-out operation are performed by controlling potentials of the bit lines BL1, BL2, BL3, and BL4, the word lines WL1, WL2, and WL3, and the gate wires GL1, GL2, GL3, and GL4, for example, as shown in FIG. 7.

Voltages of 5V, 4V, and 2V are applied to the word line WL1 at the reset operation time, at the set operation time, and at the read-out operation time, respectively, like the above-described explanation using FIG. 6. The potentials of the other terminals shown in FIG. 7 also represent the potentials at the reset operation time, at the set operation time, and at the read-out operation time starting from the left.

In the vertical chain memory whose bit line side has been connected to the bit line BL2, BL3 or BL4 and whose word line side has been connected to the word line WL1, both the potentials of the bit line and the word line are 5V at the reset operation time, 4V at the set operation time, and 2V at the read-out operation time, where no potential difference occurs so that current does not flow.

In the vertical chain memory whose bit line side has been connected to the bit line BL1 and whose word line side has been connected to the word line WL2 or WL3, both the potentials of the bit line and the word line are 0V at the reset operation time, at the set operation time, and at the read-out operation time, no potential difference occurs, so that current does not flow.

In the vertical chain memory whose bit line side has been connected to the bit line BL2, BL3 or BL4 and whose word line side has been connected to the word line WL2 or WL3, voltages of 0V and 5V are applied to the word line and the bit line at the reset operation time, respectively, voltages of 0V and 4V are applied to the word line and the bit line at the set operation time, respectively, and voltages of 0V and 2V are applied to the word line and the bit line at the read-out operation time, respectively.

A voltage is applied in a reverse bias direction of the diode PD selecting the vertical chain memory. Manufacture is performed such that the withstanding voltage of the diode PD exceeds 5V, so that flow of current can be prevented. Therefore, current can be caused to flow in only the vertical chain memory whose bit line side has been connected to the bit line BL1 and whose word line side has been connected to the word line WL1 by applying a forward bias to the diode PD. According to the method explained in FIG. 6, since a desired memory cell in the vertical chain memory can be selected to be operated, a desired memory cell in the memory array shown in FIG. 7 can be selected to be operated.

Incidentally, here, the explanation has been made assuming that the potentials at the reset operation time, at the set operation time, and at the read-out operation time are 5V/4V/2V, respectively. However, the potentials become higher in the order of the reset operation time, the set operation time, and the read-out operation time, but since a voltage required for operation fluctuates according to a circuit element to be utilized, the respective voltages are not limited to the above-described voltages.

As shown in FIG. 6, the chain-type memory array using the phase-change film 121 has a stacked body obtained by forming the gate polysilicon layers 21p, 22p, 23p, and 24p and the insulating layers 11, 12, 13, 14, and 15 alternately, and the memory cell is formed by providing the channel layer 112 made of polysilicon and the phase-change film 121 inside a through-hole extending through the stacked body. The reaction-preventing film 113 is provided between the channel layer 112 and the phase-change film 121, but it is not provided over the whole side wall within the through-hole but it is split in a vertical direction. According to this configuration, when memory cell selection is performed, it is avoided that current flows across the reaction-preventing film 113, and an operation can be realized with a further low voltage.

Further, in this embodiment, the metal silicide film 115 is formed in the connection portion between memory cells, namely, in a region corresponding to a height of formation of each of the insulating film 11, 12, 13, 14 and 15 between the gates within the through-hole. According to this configuration, the resistance of the connection portion between memory cells is lowered, so that an operation can be realized with a further low voltage.

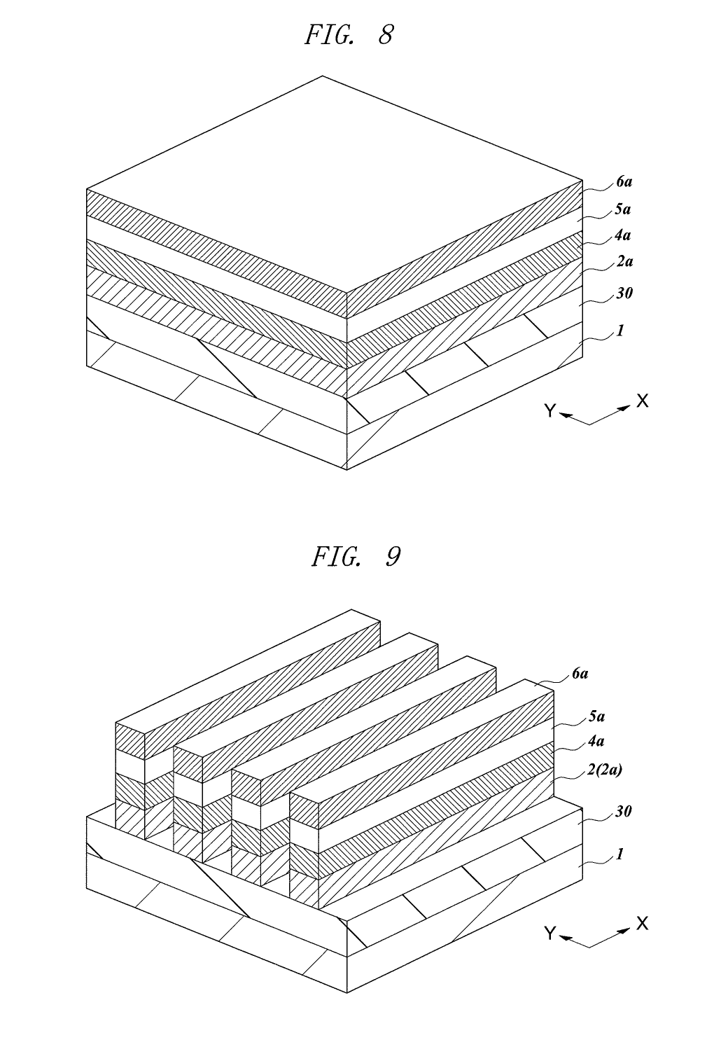

Next, a manufacturing method of a semiconductor storage device according to the embodiment will be described with reference to FIG. 8 to FIG. 27.

First of all, as shown in FIG. 8 (a perspective view of a memory cell array corresponding to FIG. 4), an insulating film 30, a tungsten film 2a constituting word lines, an amorphous silicon layer 4a doped with p-type impurities, an amorphous silicon layer 5a doped with a low-level impurities, and an amorphous silicon layer 6a doped with n-type impurities are deposited on a semiconductor substrate 1 composed of single crystal silicon in this order. Incidentally, though illustration is omitted, the peripheral circuits shown in FIG. 2 and the word line contacts WLC shown in FIG. 3 are formed around the memory cell array region shown in FIG. 8 in advance.

Next, as shown in FIG. 9, the amorphous silicon layers 4a, 5a, and 6a and the tungsten film 2a are patterned in a stripe shape along an X direction (word line direction) in FIG. 9 by using the known photolithography technique to form word lines 2 composed of the tungsten film 2a. When the word lines 2 are formed according to a self-aligned process to the amorphous silicon layers 4a, 5a, and 6a in this manner, since no positional deviation occurs between the stripe-like amorphous silicon layers 4a, 5a and 6a and the word lines 2 regarding the word line direction, reliability of the rewriting operation of the memory cell can be enhanced.

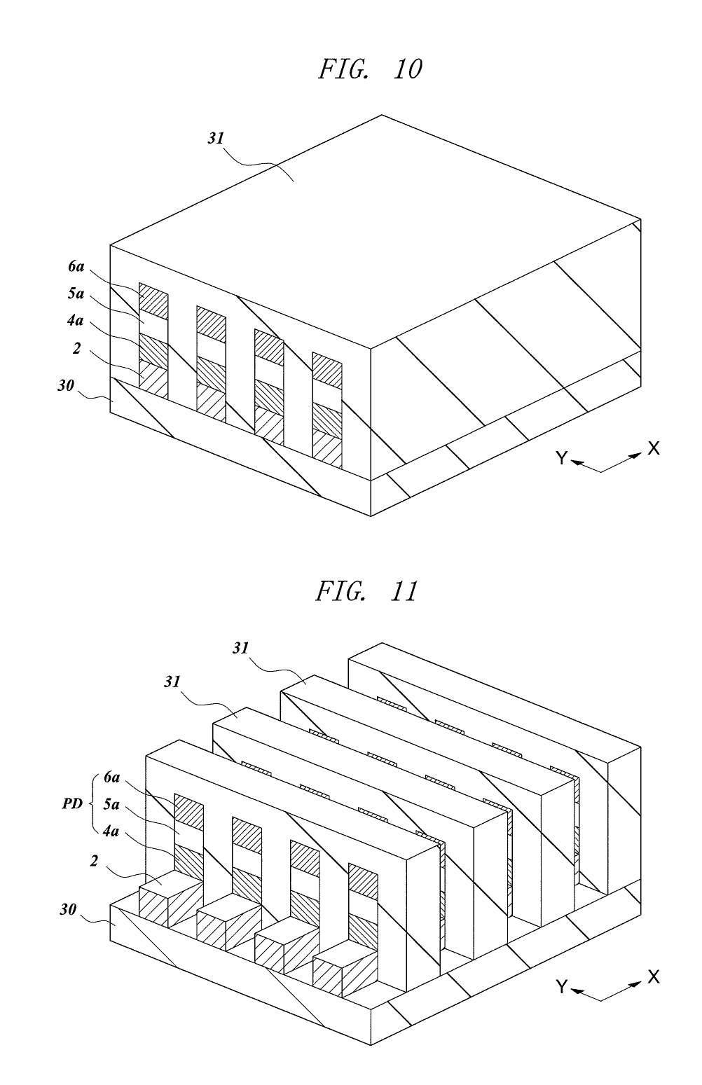

Next, as shown in FIG. 10, after an insulating film 31 is embedded in spaces among sets of the amorphous silicon layers 4a, 5a, and 6a and the work lines 2, as shown in FIG. 11, the insulating film 31 and the amorphous silicon layers 4a, 5a, and 6a are patterned in a stripe shape along a Y direction in FIG. 11 to form square pillar-shaped diodes PD composed of the amorphous silicon layers 4a, 5a and 6a, on the word lines 2.

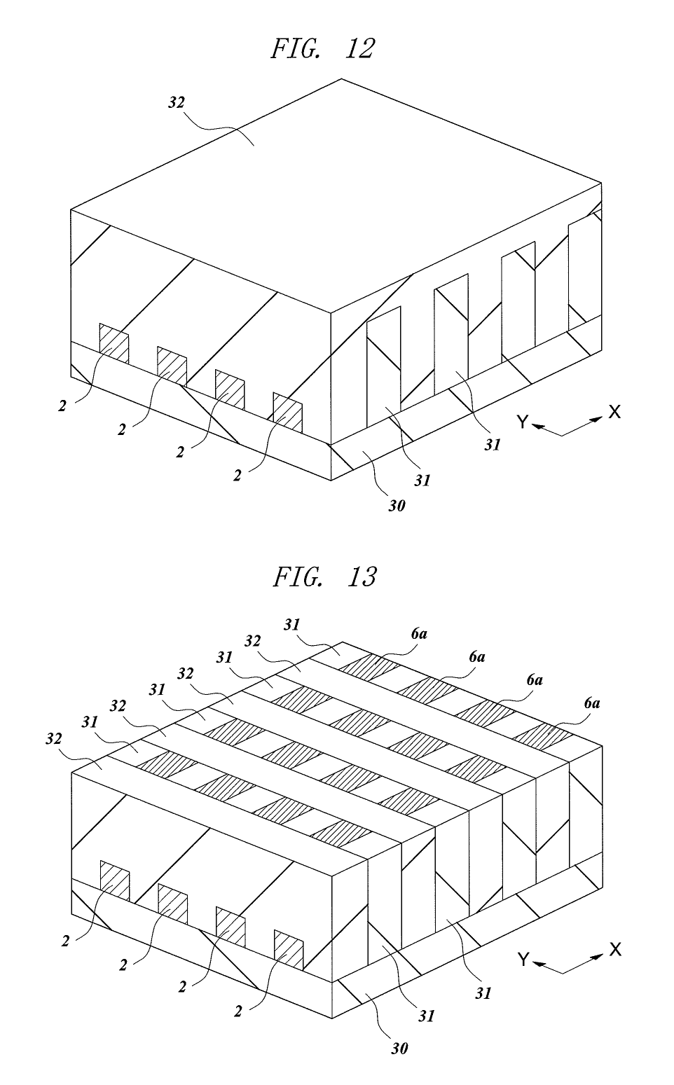

Next, as shown in FIG. 12, after an insulating film 32 covering the diodes PD and the insulating film 31 is deposited, as shown in FIG. 13, portions of the insulating films 31 and 32 are removed by a chemical mechanical polishing (CMP) method, so that upper faces (amorphous silicon layer 6a) of the diodes PD are exposed.

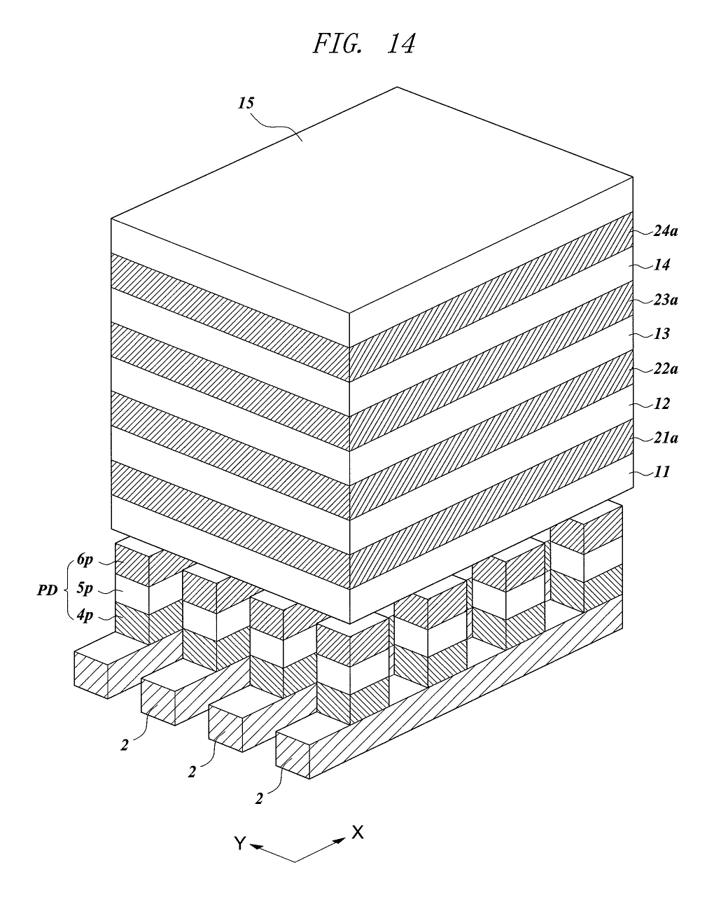

Next, as shown in FIG. 14, an insulating film 11, an amorphous silicon layer 21a, an insulating film 12, an amorphous silicon layer 22a, an insulating film 13, an amorphous silicon layer 23a, an insulating film 14, an amorphous silicon layer 24a, and an insulating film 15 are deposited on the diodes PD in this order.

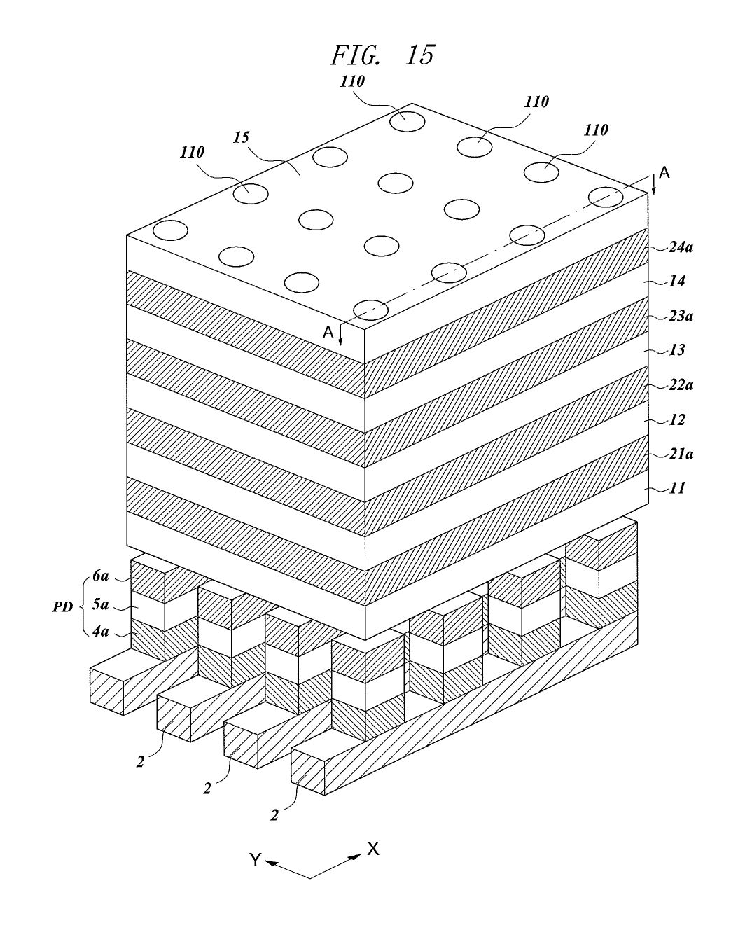

Next, as shown in FIG. 15, through-holes 110 extending through the stacked film which has been deposited at step shown in FIG. 14 to reach the upper faces (amorphous silicon layer 6a) of the diodes PD from an upper face of the insulating film 15 are formed. Incidentally, in FIG. 14 and FIG. 15, illustration of the insulating films 31 and 32 isolating diodes PD adjacent to each other electrically are omitted.

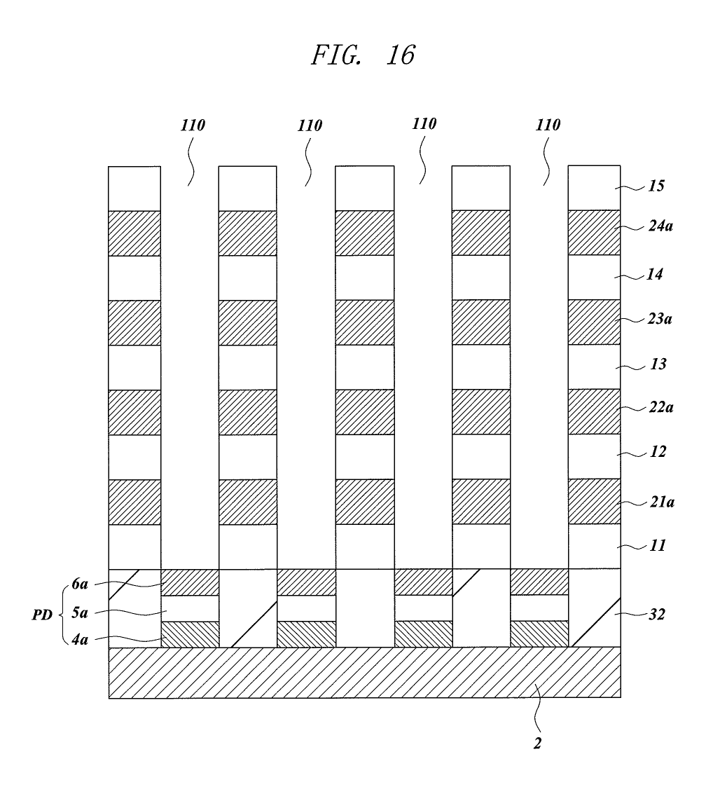

FIG. 16 is a sectional view taken along line A-A in FIG. 15. As shown in FIG. 16, a diameter of a bottom face of the through-hole 110 may be set to be approximately equal to the length of one side of the upper face of the diode PD, but it may be made smaller than the length of the one side of the upper face of the diode PD. Thereby, a margin for absorbing a positional deviation between the through-hole 110 and the diode PD can be secured. Further, since a variation of a contact area between the channel film 112 and the diode PD formed inside the through-hole 110 at steps performed later can be reduced, reduction of a current route can be suppressed.

Further, though omitted in FIG. 15, as shown in FIG. 13, the insulating films 31 and 32 are embedded around the diode PD. Therefore, if a positional deviation between the through-hole 110 and the diode PD occurs when the through-hole 110 is formed, there is a possibility that the insulating films 31 and/or 32 around the diode PD are ground.

As a measure to such a problem, it is desirable that the insulating films 31 and 32, and the insulating films 11 to 15 are constituted of insulating materials different in etching selectivity. Thereby, even if a positional deviation occurs between the through-hole 110 and the diode PD, the grinding to the insulating films 31 and 32 can be kept to the minimum. Therefore, such a drawback that a material other than the insulating material is embedded into a space occurring due to the grinding of the insulating materials 31 and 32 can be prevented, so that operation reliability of the memory cell can be enhanced. A combination of insulating materials different in etching selectivity can involve a combination of a silicon oxide film and a silicon nitride film, for example.

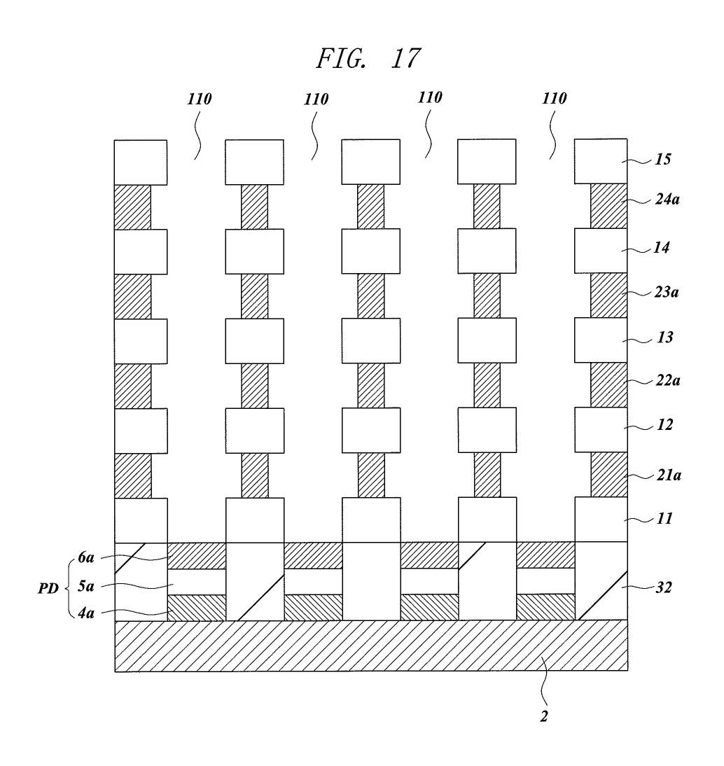

Next, as shown in FIG. 17, the insides of the through holes are etched under such a condition that silicon (the amorphous silicon layers 21a, 22a, 23a, and 24a) is isotropically-etched without etching the insulating films 11 to 15, the amorphous silicon layers 21a, 22a, 23a, and 24a exposed on the side walls of the through-holes 110 are set back. At this time, since surfaces of the amorphous silicon layer 6a of the diodes PD exposed on the bottoms of the through-holes 110 are also etched, it is desirable that the amorphous silicon layer 6a are formed to be thick in advance considering the etching amount at this step.

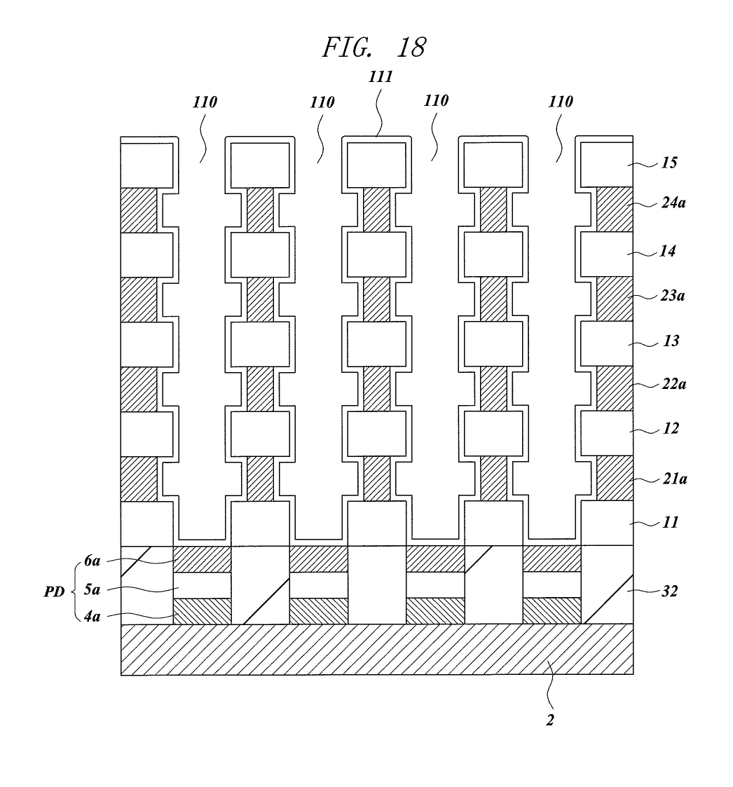

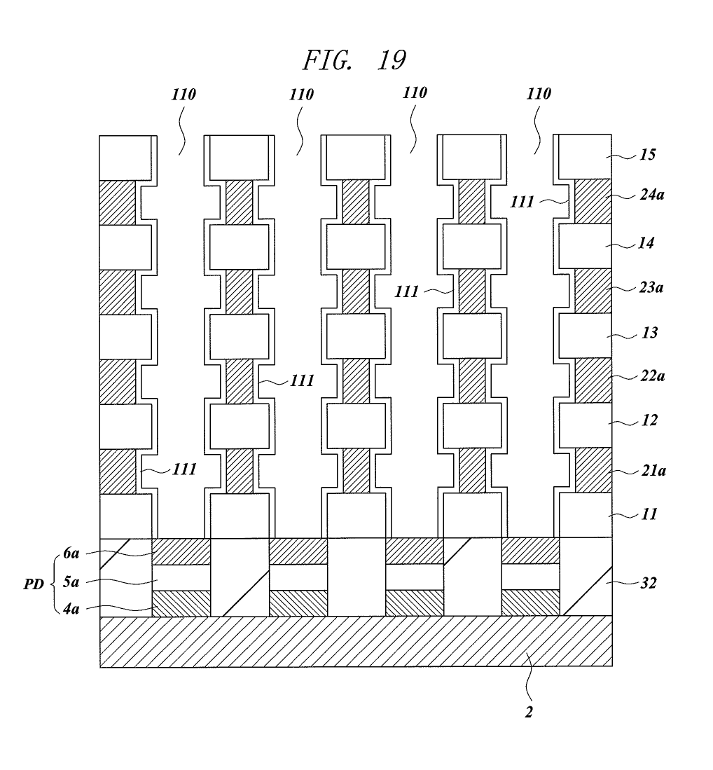

Next, as shown in FIG. 18, after a gate insulating film 111 is formed so as to cover upper faces of the insulating films 15 and side walls and bottom faces of the through-holes 110, as shown in FIG. 19, the insulating film 111 on the upper faces of the insulating films 15 and the bottoms of the through-holes 110 are removed by anisotropic etching to leave the gate insulating films 111 on the side walls of the through-holes 110.

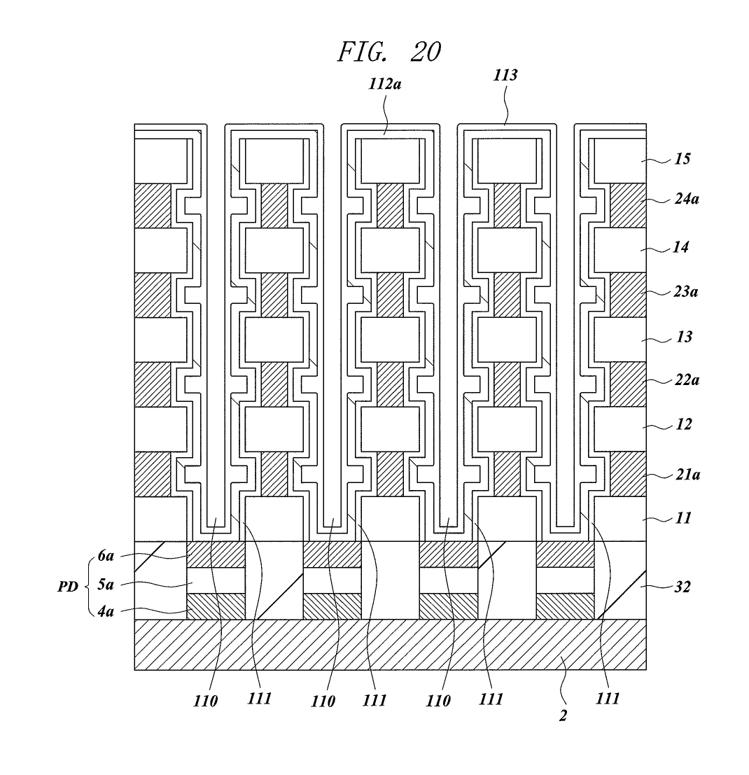

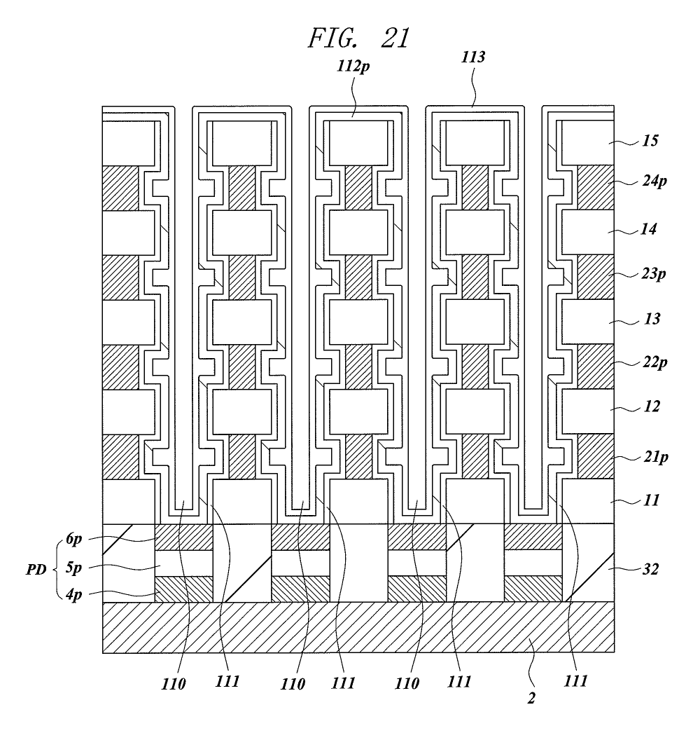

Next, as shown in FIG. 20, after a reaction-preventing film 113 composed of an amorphous silicon layer 112a and silicon nitride is formed so as to cover upper faces of the insulating films 15 and side walls and bottom faces of the through-holes 110, thermal treatment is performed for crystallization of the amorphous silicon layers 4a, 5a, 6a, 112a, 21a, 22a, 23a, and 24a and activation of impurities contained therein.

As shown in FIG. 21, the amorphous silicon layers 4a, 5a, and 6a constituting the diodes PD are changed to polysilicon layers 4p, 5p, and 6p according to the thermal treatment, respectively. Further, the amorphous silicon layers 21a, 22a, 23a, and 24a are changed to gate polysilicon layers 21p, 22p, 23p, and 24p and the amorphous silicon layer 112a is changed to a polysilicon layer 112p.

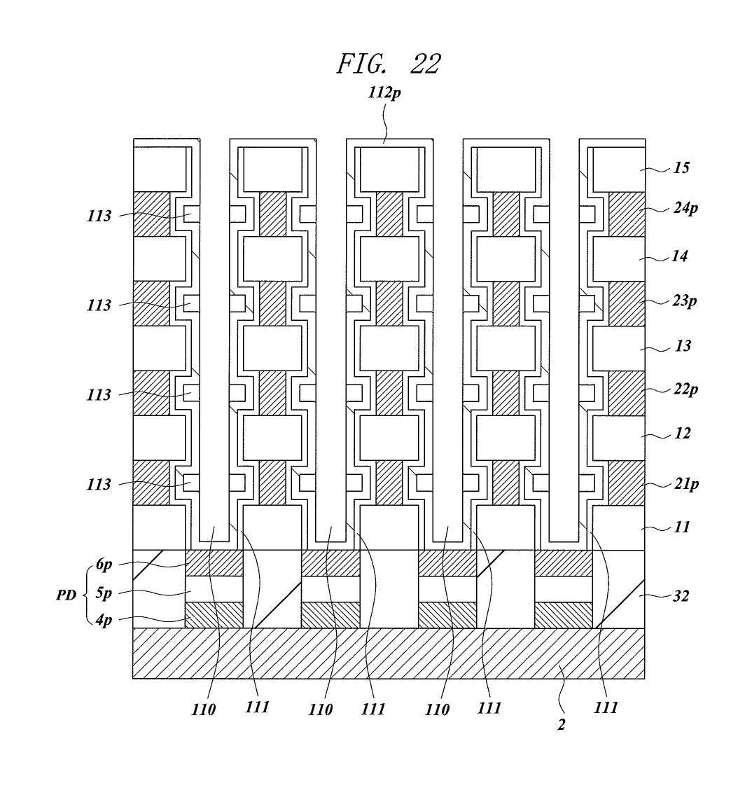

Next, as shown in FIG. 22, the reaction-preventing film 113 is anisotropically-etched to be left on only portions (regions where the amorphous silicon layers 21a, 22a, 23a, and 24a have been set back at the step shown in FIG. 17) of the side walls of the through-holes 110.

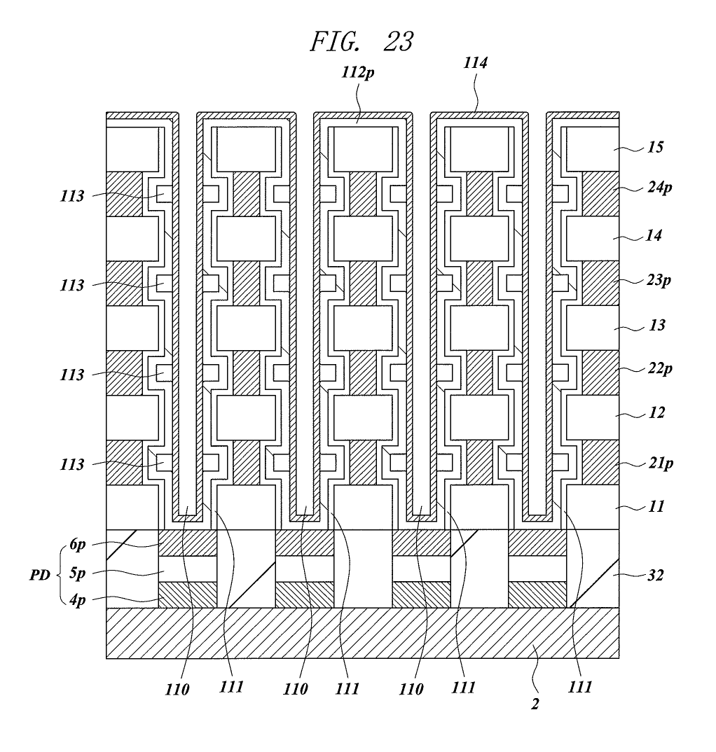

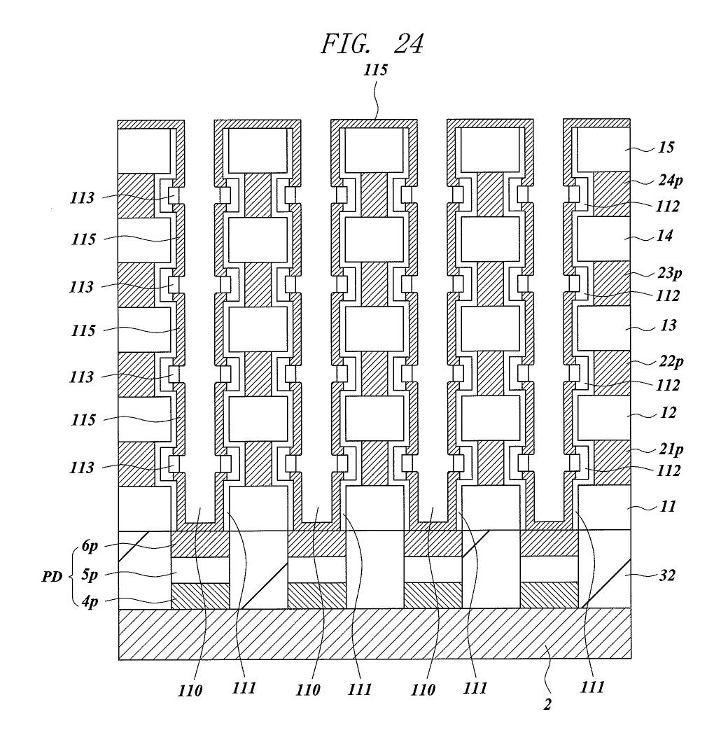

Next, as shown in FIG. 23, a metal film 114 is formed so as to cover the upper faces of the insulating films 15 and side walls and bottom faces of the through-holes 110. As a material for the metal film 114, a material which reacts with silicon at a low temperature of 800° C. or less to form a low-resistant silicide compound, for example, titanium, nickel, cobalt or the like is preferred.

Next, as shown in FIG. 24, after a metal silicide film 115 is formed by causing the polysilicon layer 112p and the metal film 114 to react with each other by thermal treatment, an unreacted metal silicide film 115 is removed by etching. The metal silicide film 115 is made of, for example, titanium silicide, nickel silicide, cobalt silicide, or the like.

When the polysilicon film 112p and the metal film 114 are caused to react with each other to form the metal silicide film 115, silicidation reaction does not occur in a region where the reaction-preventing film 113 is formed between the polysilicon layer 112p ad the metal film 114, so that the channel film 112 is formed from the polysilicon layer 112p remaining in this region.

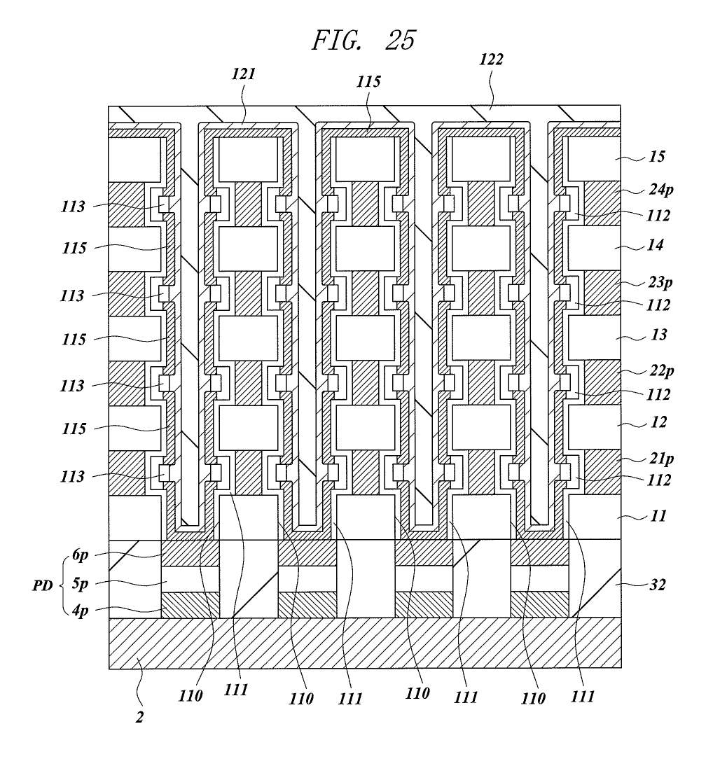

Next, as shown in FIG. 25, a phase-change film 121 and an embedding insulating film 122 are formed inside the through-holes 110. At this time, the embedding insulating film 122 is formed so as to be completely filled in the through-holes 110.

Incidentally, insides of the through-holes 110 may be embedded with only the phase-change film 121 without using the embedding insulating film 122. However, in the case that the insides of the through-holes 110 are completely filled with the embedding insulating film 122, when the gate is turned OFF at an operation of the memory cell so that when current flows in the phase-change film 121, current does not flow in a portion where the embedding insulating film 122 has been formed. Thereby, since a route of current flowing in the phase-change film 121 can be partially limited to reduce a region where change of a resistance value occurs, an operation of the memory cell can be performed with a further reduced current.

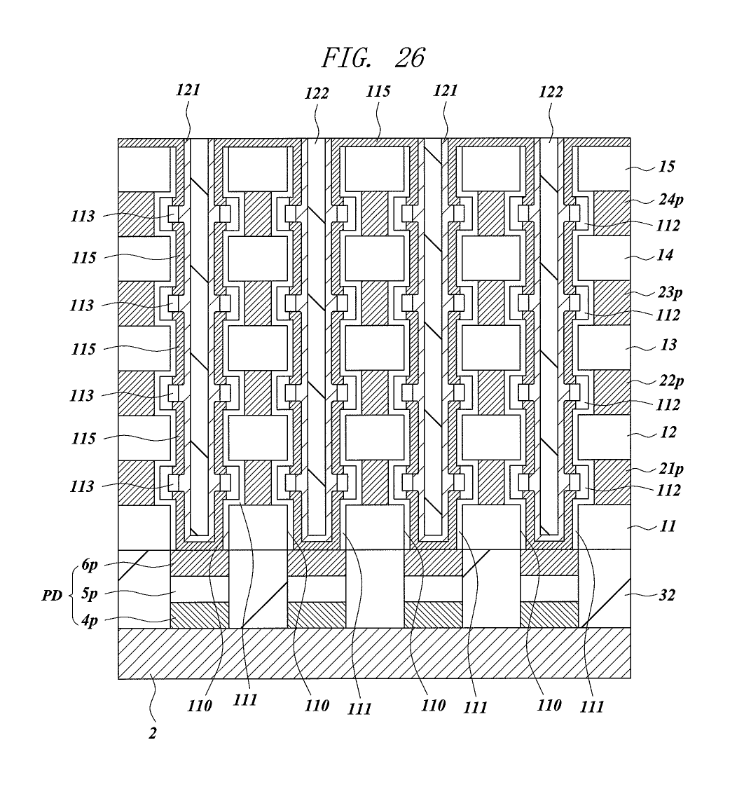

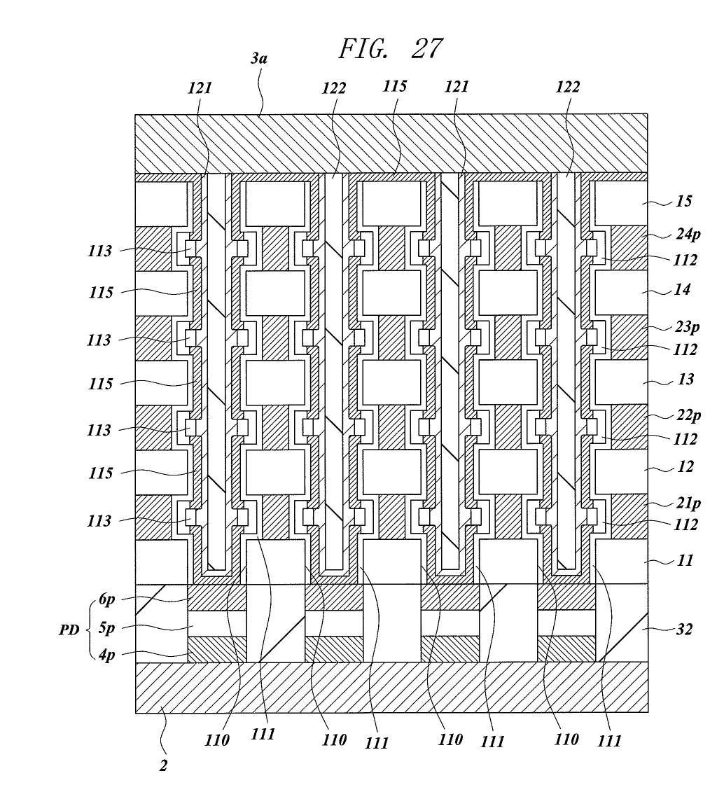

Next, as shown in FIG. 26, after the phase-change film 121 and the embedding insulating film 122 positioned outside the through-holes 110 are removed by etching-back, as shown in FIG. 27, a tungsten film 3a constituting bit lines is formed.

Thereafter, the tungsten film 3a is patterned in a stripe fashion along a direction (Y direction) perpendicular to the word lines 2 to form bit lines 3, so that the memory cell array shown in FIG. 4 is completed.

In the foregoing, the invention made by the present inventors has been concretely described based on the embodiment. However, it is needless to say that the present invention is not limited to the foregoing embodiment and various modifications and alterations can be made within the scope of the present invention.

The present invention can be utilized in a semiconductor storage device having a phase-change memory.

What is claimed is:

1. A semiconductor storage device where a plurality of memory cells obtained by connecting a vertical transistor and a phase-change element whose resistant value is changed by current in parallel is formed along a first direction perpendicular to a main face of a semiconductor substrate, wherein
a stacked body obtained by stacking (N+1) insulating layers and N gate semiconductor layers alternately and a plurality of through-holes extending through the stacked body in the first direction are formed on the main face of the semiconductor substrate, where N is a natural number,
a gate insulating film of the vertical transistor, a channel film of the vertical transistor, a reaction-preventing film, and a phase-change film constituting the phase-change element are formed inside each of the plurality of through-holes, and
the reaction-preventing film is separated into respective pieces at regions among the plurality of memory cells formed along the first direction.

2. The semiconductor storage device according to claim 1, wherein
an embedding insulating film is formed inside each of the plurality of through-holes at a position closer to a center side of the through-hole than the phase-change film is.

3. A semiconductor storage device where a plurality of memory cells obtained by connecting a vertical transistor and a phase-change element whose resistant value is changed by current in parallel is formed along a first direction perpendicular to a main face of a semiconductor substrate, wherein
a stacked body obtained by stacking (N+1) insulating layers and N gate semiconductor layers alternately and a plurality of through-holes extending through the stacked body in the first direction are formed on the main face of the semiconductor substrate, where N is a natural number,
a gate insulating film of the vertical transistor, a channel film of the vertical transistor, a metal silicide film, and a phase-change film constituting the phase-change element are formed inside each of the plurality of through-holes, and
the channel film is separated into respective pieces at regions among the plurality of memory cells formed along the first direction, and besides, the channel films are connected to each other via the metal silicide film.

4. The semiconductor storage device according to claim 3, wherein
a buried insulating film is formed inside each of the plurality of through-holes at a position closer to a center side than the phase-change film.

5. The semiconductor storage device according to claim 4, wherein
the metal silicide film is made of titanium silicide, nickel silicide, or cobalt silicide.

6. A manufacturing method of a semiconductor storage device where a plurality of memory cells obtained by connecting a vertical transistor and a phase-change element whose resistant value is changed by current in parallel is formed along a first direction perpendicular to a main face of a semiconductor substrate, comprising:
(a) a step of forming a stacked body obtained by stacking (N+1) insulating layers and N gate semiconductor layers alternately on the main face of the semiconductor substrate, where N is a natural number;
(b) a step of forming a plurality of through-holes extending through the stacked body along the first direction;
(c) a step of isotropically-etching the N gate semiconductor layers exposed to side walls of insides of the plurality of through-holes to perform setting-back laterally;
(d) a step of embedding a gate insulating film of the vertical transistor, a channel film of the vertical transistor, and a reaction-preventing film into the plurality of through-holes in this order after the step (c);
(e) a step of anisotropically-etching the reaction-preventing film to separate the reaction-preventing film into respective pieces at regions among the plurality of memory cells formed in the first direction; and
(f) a step of embedding a phase-change film constituting the phase-change element into the plurality of through-holes after the step (e).

7. The manufacturing method of a semiconductor storage device according to claim 6, further comprising: after the step (e) and before the step (f),
(g) a step of embedding a metal film into the plurality of through-holes;
(h) a step of causing the channel film and the metal film in a region between the memory cells to react with each other to form a metal silicide film by thermal treatment; and
(i) a step of removing an unreacted portion of the metal film by etching after the step (h).

8. The manufacturing method of a semiconductor storage device according to claim 6, wherein
after the step (f), an embedding insulating film is formed in the plurality of through-holes.

9. The manufacturing method of a semiconductor storage device according to claim 6, wherein
the N gate semiconductor layers are made of polysilicon.

10. The manufacturing method of a semiconductor storage device according to claim 7, wherein
the metal silicide film is made of titanium silicide, nickel silicide, or cobalt silicide.
